(19) United States
(12) Patent Application Publication
(10) Pub. No.: US 2025/0224433 A1
(43) Pub. Date: Jul. 10, 2025

(54) MEASUREMENT INSTRUMENT

(71) Applicant: Rohde & Schwarz GmbH & Co. KG, Muenchen (DE)

(72) Inventors: Susanne HIRSCHMANN, Muenchen (DE); Florian RAMIAN, Muenchen (DE)

(21) Appl. No.: 18/967,067

(22) Filed: Dec. 3, 2024

(30) Foreign Application Priority Data
Jan. 9, 2024 (EP) 24 151 037.9

(51) Int. Cl. G01R 27/28; G01R 13/22; G01R 23/16

(52) U.S. Cl. CPC G01R 27/28; G01R 13/22; G01R 23/16

(57) ABSTRACT

A measurement instrument includes at least one input port and a measurement circuit. The input port is configured to receive a radio frequency (RF) signal from a device under test, wherein the RF signal comprises a symbol sequence. The measurement circuit is configured to receive the RF signal from the input port. The measurement circuit includes a reference signal circuit, wherein the reference signal circuit is configured to generate a reference signal based on the received RF signal, wherein the reference signal comprises an extracted symbol sequence corresponding to the symbol sequence of the RF signal. The measurement circuit further comprises an error circuit, wherein the error circuit is configured to determine error vectors based on the RF signal and based on the reference signal. The measurement circuit further includes an analysis configured to determine whether the reference signal is correct based on the determined error vectors.

### CROSS REFERENCE TO RELATED APPLICATION

The present application claims priority to European Application No. 24151037.9, filed on Jan. 9, 2024, the entire contents of which are incorporated herein by reference.

### FIELD OF THE DISCLOSURE

Embodiments of the present disclosure generally relate to a measurement instrument.

### BACKGROUND

For different types of measurement applications, a reference signal that corresponds to an ideal version of a received RF signal is extracted from the RF signal.

For these measurements to be correct, it is required that the extracted reference signal comprises the same symbol sequence as the RF signal.

Under certain circumstances, e.g. if the RF signal has a low signal-to-noise ratio, detection errors may occur, i.e. individual symbols of the symbol sequence in the extracted reference signal may be incorrect.

In the state of the art, the actual symbol sequence comprised in the RF signal has to be known in order to avoid or correct such detection errors.

However, there are situations where the actual symbol sequence is not known. In these measurement scenarios, the detection errors describe above cannot be corrected reliably.

Thus, there is a need for a measurement instrument that is capable of reliably detecting detection errors.

### SUMMARY

Embodiments of the present disclosure provide a measurement instrument. In an embodiment, the measurement instrument comprises at least one input port and a measurement circuit. The input port is configured to receive a radio frequency (RF) signal from a device under test, wherein the RF signal comprises a symbol sequence. The measurement circuit is configured to receive the RF signal from the input port. The measurement circuit comprises a reference signal circuit, wherein the reference signal circuit is configured to generate a reference signal based on the received RF signal, wherein the reference signal comprises an extracted symbol sequence corresponding to the symbol sequence of the RF signal. The measurement circuit further comprises an error circuit, wherein the error circuit is configured to determine error vectors based on the RF signal and based on the reference signal. The measurement circuit further comprises an analysis circuit, wherein the analysis circuit is configured to determine whether the reference signal is correct based on the determined error vectors.

As used herein, the term “error vector” is understood to denote a vector that is equal to a difference between the RF signal and the reference signal at a certain point, namely at the symbol instance. For example, each error vector is equal to a difference between a sample of the RF signal and the corresponding sample of reference signal. As an example, if the RF signal is an IQ modulated signal, each error vector is a difference between one of samples of the RF signal and the corresponding constellation point.

Embodiment of the present disclosure is based on the finding that the correctness of the reference signal can be assessed based on the determined error vectors, as will be described in more detail hereinafter.

As will be described in more detail below, it is not necessary to know the actual symbol sequence that is comprised in the RF signal. Instead, the correctness of the reference signal and thus the correctness of measurements performed can be assessed based on the RF signal and the extracted reference signal alone. Thus, the measurement instrument according to embodiments of the present disclosure is capable of detecting errors in the extracted reference signal even if details of the RF signal, for example the symbol sequence comprised in the RF signal, are unknown.

According to an aspect of the present disclosure, the analysis circuit, for example, is configured to determine an error distribution based on the error vectors. In an embodiment, the analysis circuit is configured to determine whether the reference signal is correct based on the determined error distribution. In general, an error distribution that is associated with a certain type of errors in the RF signal has a certain expected shape. Conversely, if the shape of the error distribution significantly differs from the expected shape, it can be concluded that an additional error has occurred, for example an error in the extracted reference signal.

For example, uncorrelated noise in the RF signal is expected to cause the error distribution to have the shape of a normal distribution or the shape of a multivariate normal distribution. If the error distribution significantly differs from the multivariate normal distribution, it may be concluded that a detection error has occurred, i.e. that at least one symbol of the extracted reference signal is incorrect.

In an embodiment, the reference signal circuit is configured to demodulate the RF signal, thereby obtaining a demodulated RF signal, wherein the reference signal circuit is configured to generate the reference signal based on the demodulated RF signal. By demodulating the RF signal, the individual symbols comprised in the RF signal can be extracted. The reference signal can then be generated based on the extracted symbols, namely as an ideal version of the RF signal comprising the extracted symbols.

In an embodiment, the modulation scheme on which the RF signal is based may be known or unknown.

According to another aspect of the present disclosure, the analysis circuit, for example, is configured to determine at least one analysis parameter. In an embodiment, the at least one analysis parameter is associated with the RF signal. In an embodiment, the analysis circuit is configured to determine at least one statistical parameter associated with the at least one analysis parameter based on the determined error vectors, wherein the at least one statistical parameter is indicative of a measurement uncertainty with respect to the at least one analysis parameter. In other words, the measurement instrument may be configured to assess the accuracy of measurements conducted on the RF signal based on the determined error vectors, wherein the at least one statistical parameter is a measure for the measurement accuracy or the measurement uncertainties.

In general, the at least one analysis parameter is a parameter that is indicative of a signal quality of the RF signal and thus of a performance of the device under test generating the RF signal.

For example, the at least one analysis parameter may be or comprise an error vector magnitude (EVM).

In an embodiment, the measurement instrument may further comprise a visualization circuit, wherein the visualization circuit is configured to generate joint visualization data for the at least one analysis parameter and for the at least one statistical parameter. Thus, information on the at least one analysis parameter and on the at least one statistical parameter may be visualized together, such that the information on the at least one analysis parameter and on the at least one statistical parameter is displayed to an user of the measurement instrument in an illustrative way.

In an embodiment, the measurement instrument may comprise a display that is configured to display the joint visualization data. Alternatively or additionally, the measurement instrument may be connectable to an external display that is configured to display the joint visualization data.

In an embodiment, the visualization data may further comprise a warning signal, such as a text message and/or a warning sign, if the analysis circuit detects that the extracted reference signal is incorrect. Thus, the user is warned that the measurements performed may be incorrect or even invalid.

Another aspect of the present disclosure provides that the analysis circuit, for example, is configured to estimate a symbol error rate of the RF signal based on the determined error vectors. In an embodiment, the symbol error rate can be estimated based on the determined error vectors without an actual symbol error occurring in the RF signal. This way, the measurement time for determining the symbol error rate of the RF signal can be reduced significantly, as the analysis circuit does not have to wait for a statistically significant amount of errors to have occurred. This is particularly advantageous for RF signals that have a low symbol error rate.

In an embodiment of the present disclosure, the analysis circuit is configured to determine an error distribution based on the error vectors, wherein the analysis circuit is configured to estimate the symbol error rate of the RF signal based on the determined error distribution. In an embodiment, the symbol error rate can be estimated based on the determined error distribution without an actual symbol error occurring in the RF signal. This way, the measurement time for determining the symbol error rate of the RF signal can be reduced significantly, as the analysis circuit does not have to wait for a statistically significant amount of errors to have occurred. This is particularly advantageous for RF signals that have a low symbol error rate.

In a further embodiment of the present disclosure, the analysis circuit is configured to estimate the symbol error rate based on portions of the determined error distribution that are outside of decision boundaries, for example wherein the analysis circuit is configured to integrate over the portions of the determined error distribution that are outside of the decision boundaries in order to estimate the symbol error rate. The decision boundaries represent lines in the IQ plane that separate the individual possible symbol values. Accordingly, by evaluating the error distribution over the portions outside of the respective decision boundaries, for example by integrating the error distribution over the portions outside of the respective decision boundaries, a measure for the probability of a constellation point lying outside of the decision boundaries is obtained, which corresponds to the probability of a symbol error.

In an embodiment, the analysis circuit may be configured to determine whether the reference signal is correct based on additional system information. This way, the accuracy of the detection of symbol errors in the extracted reference signal may be enhanced.

In an embodiment, the additional system information may relate to what type of errors are to be expected in the RF signal. For example, the additional system information may comprise the type of noise to be expected, e.g. only uncorrelated noise. As another example, the additional system information may comprise information on whether non-linear behavior of the RF signal is to be expected.

In an embodiment of the present disclosure, the symbol sequence comprised in the RF signal is unknown to the measurement circuit. Thus, the measurement instrument is configured to detect errors in the extracted reference signal without a priori knowledge of the symbol sequence comprised in the RF signal. Accordingly, measurements can be conducted reliably even if the symbol sequence is unknown.

According to an aspect of the present disclosure, a modulation scheme of the RF signal, for example, is unknown to the measurement circuit. In an embodiment, the measurement circuit may be configured to determine the modulation scheme of the RF signal based on the RF signal, for example based on a constellation diagram of the RF signal. Thus, the measurement instrument is configured to detect errors in the extracted reference signal without a priori knowledge of the modulation scheme of the RF signal.

In a further embodiment of the present disclosure, the analysis circuit is configured to determine erroneous error vectors, for example erroneous components of the erroneous error vectors. In other words, the analysis circuit may be configured to identify the individual error vectors that are incorrect, i.e. error vectors that refer to a falsely extracted symbol value.

In an embodiment, the analysis circuit is configured to correct the determined erroneous error vectors. This way, the accuracy of measurements conducted on the RF signal can be enhanced, as the erroneous error vectors may be corrected for the measurements.

For example, the accuracy of the at least one analysis parameter described above can be enhanced, as the erroneous error vectors may be corrected before determining the at least one analysis parameter.

As another example, the symbol error rate can be estimated with enhanced accuracy, as the erroneous error vectors may be corrected before determining the error distribution.

In another embodiment of the present disclosure, the analysis circuit is configured to discard the determined erroneous error vectors. This way, the accuracy of measurements conducted on the RF signal can be enhanced, as the erroneous error vectors may be discarded for the measurements.

For example, the accuracy of the at least one analysis parameter described above can be enhanced as the erroneous error vectors may be discarded before determining the at least one analysis parameter.

As another example, the symbol error rate can be estimated with enhanced accuracy, as the erroneous error vectors may be discarded before determining the error distribution.

A further aspect of the present disclosure provides that the measurement instrument, for example, is a signal analyzer, a spectrum analyzer, or an oscilloscope. However, it is to be understood that the measurement instrument may be established as any other suitable type of measurement instrument.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a measurement system with a measurement instrument according to an embodiment of the present disclosure;

FIG. 2 schematically shows an example constellation diagram of an RF signal;

FIG. 3 shows a single constellation point of the constellation diagram in more detail;

FIG. 4 shows the constellation point of FIG. 2 with an additional error being present; and

FIG. 5 shows the constellation point of FIG. 2 with the associated decision boundaries.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

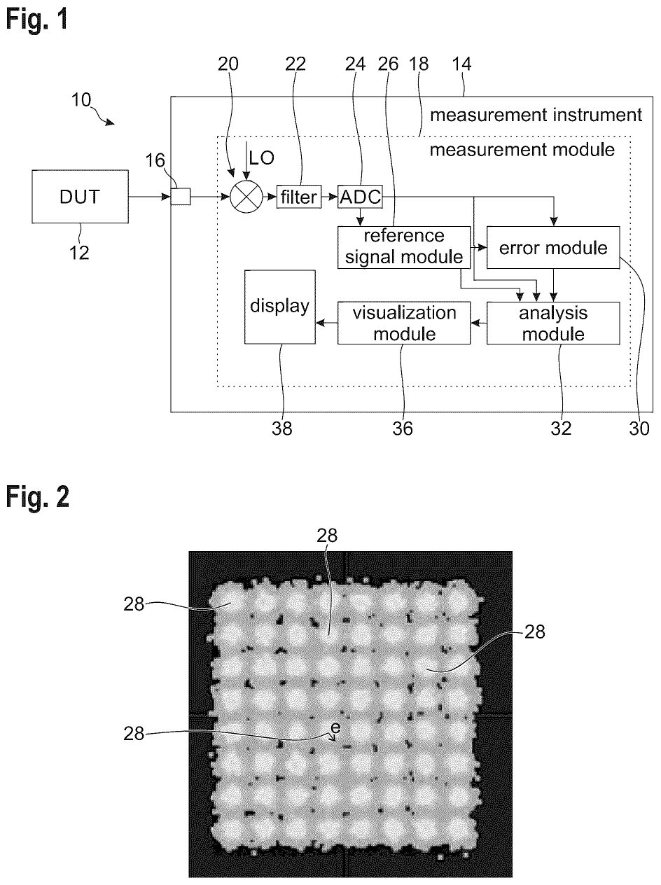

FIG. 1 schematically shows a representative measurement system 10 comprising a device under test (DUT) 12 and a measurement instrument 14 in accordance with an embodiment of the present disclosure. In general, the device under test 12 may be any type of electronic device that is configured to generate an RF signal or that is configured to process an input signal, thereby obtaining an RF signal, wherein the RF signal is an IQ modulated signal.

For example, the device under test 12 may be an amplifier, an attenuator, a filter, or a mixer. As another example, the device under test 12 may be a signal generator, a mobile communication device, a network device such as a router, etc. However, it is to be understood that the device under test 12 may be any other type of electronic device being configured to generate and/or process RF signals comprising a symbol sequence.

Generally, the measurement instrument 14 is configured to conduct measurements on the device under test 12 in order to assess a performance of the device under test 12. In an embodiment, the measurement instrument 14 comprises an input port 16 that is configured to receive an output signal of the device under test 12, i.e. the RF signal described above. It is noted that the measurement instrument 14 may, of course, comprise further input ports.

In the example embodiment shown in FIG. 1, an output of the device under test 12 is connected to the input port 16 by a cable. However, it is to be understood that a wireless connection between the device under test 12 and the measurement instrument 14 is also possible. In this case, the input port 16 may comprise or be connected to an RF antenna that is configured to receive the wireless RF signal from the device under test 12.

In an embodiment, the measurement instrument 14 further comprises a measurement circuit 18 that is connected to the input port 16 so as to receive the RF signal. Optionally, the measurement circuit 18 may comprise a mixer circuit 20 that is configured to down-convert a frequency of the RF signal by mixing the RF signal with a local oscillator (LO) signal. Optionally, the measurement circuit 18 may further comprise a filter circuit 22 that is configured to filter the down-converted RF signal.

Hereinafter, the term “RF signal” is used to denote the RF signal received from the device under test 12 or the down-converted RF signal, depending on whether the mixer circuit 20 and the filter circuit 22 are provided or not.

In an embodiment, the measurement circuit 18 further comprises an analog-to-digital converter (ADC) 24 that is configured to digitize the RF signal, thereby obtaining a digitized RF signal. Downstream of the ADC 24, a reference signal circuit 26 is provided. In general, the reference signal circuit 26 is configured to generate a reference signal based on the digitized RF signal, wherein the reference signal comprises an extracted symbol sequence corresponding to the symbol sequence of the RF signal.

In an embodiment, the reference signal circuit 26 may first demodulate the digitized RF signal, thereby obtaining a demodulated RF signal, and may then generate the reference signal based on the demodulated RF signal. Therein, the modulation scheme of the RF signal may be known, i.e. the reference signal circuit 26 may demodulate the RF signal based on the a priori known modulation scheme.

If the modulation scheme of the RF signal is not known, the reference signal circuit 26 may determine the modulation scheme based on the digitized RF signal, for example based on a constellation diagram of the digitized RF signal.

As is illustrated in FIG. 2, the constellation diagram of the digitized RF signal typically comprises samples of the digitized RFs signal that aggregate around the different possible constellation points 28 that correspond to the different possible symbol values. Conversely, the different possible constellation points 28, and thus the modulation scheme, can be derived from the distribution of the samples of the digitized RF signal in the constellation diagram, i.e. in the IQ plane.

In an embodiment, the reference signal circuit 26 extracts the symbols comprised in the demodulated RF signal and generates a corresponding ideal version of the RF signal comprising the same symbol sequence, i.e. the reference signal. Therein, no a priori knowledge of the symbol sequence comprised in the RF signal is required.

As is shown in FIG. 1, the measurement circuit 18 further comprises an error circuit 30 that is connected to the reference signal circuit 26 so as to receive the generated reference signal. The error circuit 30 is connected to the ADC 24 so as to receive the digitized RF signal. Generally, the error circuit 30 is configured to determine error vectors based on the digitized RF signal and based on the generated reference signal. Each error vector corresponds to a difference between an actual value of a sample of the digitized RF signal and the corresponding sample of the reference signal.

As is illustrated for one sample in FIG. 2, the error vector e corresponds to the vector from the ideal sample value, namely from the associated constellation point 28, to the actual sample value.

In an embodiment, the determined error vectors are forwarded to an analysis circuit 32 that is provided downstream of the error circuit 30. The analysis circuit 32 further may be connected to the ADC 24 so as to receive the digitized RF signal. Moreover, the analysis circuit 32 may be connected to the reference signal circuit 26 so as to receive the reference signal.

In general, the analysis circuit 32 is configured to determine whether the reference signal is correct based on the error vectors determined by the error circuit 30. For example, the analysis circuit 32 is configured to determine an error distribution based on the error vector, wherein the error distribution D(I,Q) describes the number or the density of error vectors as a function of I and Q, i.e. of the variables that span the IQ-plane.

Typically, the error distribution has the shape of a multivariate normal distribution around the individual constellation points 28. For example, the error distribution typically has the shape of a bivariate normal distribution around the individual constellation points 28. Accordingly, the error distribution for the whole IQ plane may be a superposition of the bivariate normal distributions around the individual constellation points 28.

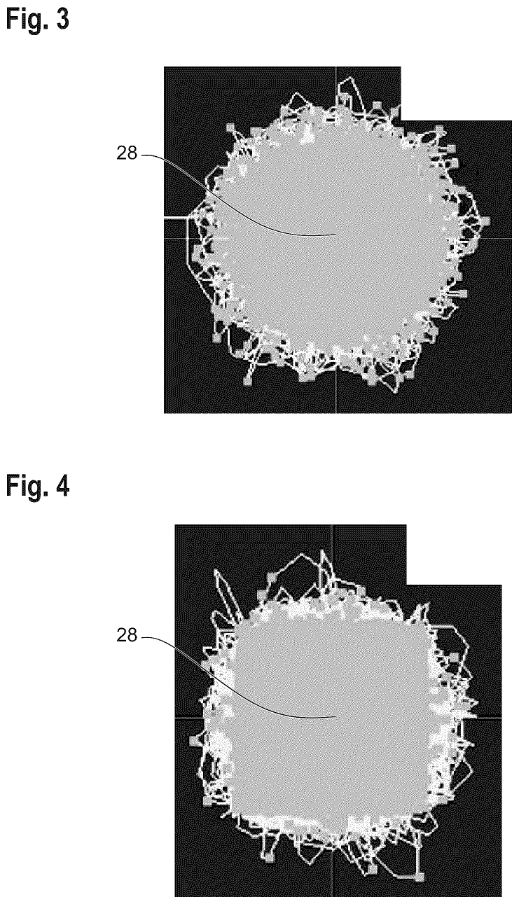

As is illustrated in FIG. 3, which shows a single constellation point 28 of the constellation diagram of FIG. 2, this corresponds to an approximately circular distribution of the individual sample points around the constellation points 28.

If the determined error distribution matches the typical shape described above for all constellation points 28, it may be concluded that the extracted reference signal is correct.

If, however, the determined error distribution differs significantly from the typical shape described above for at least one of the constellation points 28, it may be concluded that there is an additional error, for example that there is an error in the extracted reference signal.

In an embodiment, the analysis circuit 32 may determine whether the extracted reference signal is correct based on the error distribution and based on additional system information.

In an embodiment, the additional system information may relate to what type of errors are to be expected in the RF signal. For example, the additional system information may comprise the type of noise to be expected, e.g. only uncorrelated noise. As another example, the additional system information may comprise information on whether non-linear behavior of the RF signal is to be expected.

Different types of errors are usually associated with different shapes of the resulting error distribution. Accordingly, if the error distribution differs from the expected shape taking into account the additional system information, it can be concluded that at least one symbol of the extracted reference signal is incorrect.

As illustrated in FIG. 4, a deviation of the error distribution from the shape of the bivariate normal distribution may also be visible in the constellation diagram. In the specific example shown in FIG. 4, the distribution of samples around the shown constellation point 28 differs from a circular distribution and has an approximately rectangular shape.

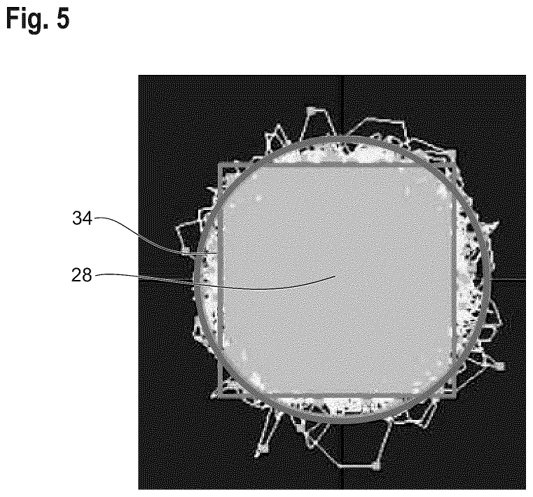

In an embodiment, the analysis circuit 32 may further be configured to estimate a symbol error rate of the RF signal based on the determined error vectors or based on the determined error distribution. As is illustrated in FIG. 5, there are decision boundaries 34 for each of the constellation points 28, which represent lines in the IQ plane that separate the individual possible symbol values.

In an embodiment, the symbol error rate (SER) can be estimated based on portions of the determined error distribution D(I,Q) that are outside of the decision boundaries 34, namely by evaluating the portions of the determined error distribution D(I,Q) that are outside of the decision boundaries 34. In an embodiment, the SER may be estimated by integrating the error distribution D(I,Q) over portions of the error distribution that are outside of the decision boundaries 34. It holds

$$SER ∝ \frac{{\int }_{{A}_{1}} D ( I , Q ) dIdQ}{\int D ( I , Q ) dIdQ} .$$

Therein, the area A_1 is the area outside of the decision boundaries 34, while the integral in the denominator spans the whole portion of the IQ plane being relevant for the error distribution, for example the whole IQ plane.

Using this way of calculating the estimated symbol error rate, the symbol error rate can be estimated based on the determined error vectors or based on the determined error distribution without an actual symbol error occurring in the RF signal, as no actual symbol error is required to determine the error distribution.

In an embodiment, the analysis circuit 32 may further be configured to determine at least one analysis parameter based on the determined error vectors, based on the reference signal, and/or based on the digitized RF signal. In general, the at least one analysis parameter is a parameter that is indicative of a performance of the device under test 12 or a signal quality of the RF signal. For example, the at least one analysis parameter may be or comprise an error vector magnitude.

In an embodiment, the analysis circuit 32 may further be configured to determine at least one statistical parameter associated with the at least one analysis parameter based on the determined error vectors, wherein the at least one statistical parameter is indicative of a measurement uncertainty with respect to the at least one analysis parameter. For example, the at least one statistical parameter may be or comprise a standard deviation, a variance, and/or higher statistical moments.

In order to enhance the accuracy of the measurements described above, the analysis circuit 32 may be configured to determine erroneous error vectors, for example erroneous components of the erroneous error vectors. Such erroneous error vectors may occur if a symbol of the reference signal has been decided incorrectly, such that the corresponding error vectors refer to the wrong constellation point 28.

In an embodiment, the analysis circuit 32 may correct the erroneous error vectors for determining the at least on analysis parameter, the at least one statistical parameter, the error distribution, and/or the estimated symbol error rate.

In an embodiment, the measurement circuit 18 further comprises a visualization circuit 36 that is connected to the analysis circuit 32. The visualization circuit 36 is configured to generate joint visualization data for the at least one analysis parameter and for the at least one statistical parameter. The joint visualization data may further comprise visualization data for the estimated symbol error rate. The joint visualization data may further comprise a warning signal, such as a text message and/or a warning sign, if the analysis circuit detects that the extracted reference signal is incorrect.

The joint visualization data may be displayed on a display 38 that is integrated into the measurement instrument 14. Alternatively or additionally, the joint visualization data may be displayed on a display that is connected to the measurement instrument 14.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the DUT 12, the measurement instrument 14, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A measurement instrument, wherein the measurement instrument comprises at least one input port and a measurement circuit,
wherein the input port is configured to receive a radio frequency (RF) signal from a device under test, wherein the RF signal comprises a symbol sequence,
wherein the measurement circuit is configured to receive the RF signal from the input port,
wherein the measurement circuit comprises a reference signal circuit, wherein the reference signal circuit is configured to generate a reference signal based on the received RF signal, wherein the reference signal comprises an extracted symbol sequence corresponding to the symbol sequence of the RF signal,
wherein the measurement circuit further comprises an error circuit, wherein the error circuit is configured to determine error vectors based on the RF signal and based on the reference signal, and
wherein the measurement circuit further comprises an analysis circuit, wherein the analysis circuit is configured to determine whether the reference signal is correct based on the determined error vectors.

2. The measurement instrument of claim 1, wherein the analysis circuit is configured to determine an error distribution based on the error vectors, and wherein the analysis circuit is configured to determine whether the reference signal is correct based on the determined error distribution.

3. The measurement instrument according to claim 1, wherein the reference signal circuit is configured to demodulate the RF signal, thereby obtaining a demodulated RF signal, and wherein the reference signal circuit is configured to generate the reference signal based on the demodulated RF signal.

4. The measurement instrument according claim 1, wherein the analysis circuit is configured to determine at least one analysis parameter, wherein the at least one analysis parameter is associated with the RF signal, and wherein the analysis circuit is configured to determine at least one statistical parameter associated with the at least one analysis parameter based on the determined error vectors, wherein the at least one statistical parameter is indicative of a measurement uncertainty with respect to the at least one analysis parameter.

5. The measurement instrument of claim 4, further comprising a visualization circuit, wherein the visualization circuit is configured to generate joint visualization data for the at least one analysis parameter and for the at least one statistical parameter.

6. The measurement instrument according to claim 1, wherein the analysis circuit is configured to estimate a symbol error rate of the RF signal based on the determined error vectors.

7. The measurement instrument of claim 6, wherein the analysis circuit is configured to determine an error distribution based on the error vectors, and wherein the analysis circuit is configured to estimate the symbol error rate of the RF signal based on the determined error distribution.

8. The measurement instrument of claim 7, wherein the analysis circuit is configured to estimate the symbol error rate based on portions of the determined error distribution that are outside of decision boundaries.

9. The measurement instrument of claim 8, wherein the analysis circuit is configured to integrate over the portions of the determined error distribution that are outside of the decision boundaries in order to estimate the symbol error rate.

10. The measurement instrument according to claim 1, wherein the analysis circuit is configured to determine whether the reference signal is correct based on additional system information.

11. The measurement instrument according to claim 1, wherein the symbol sequence comprised in the RF signal is unknown to the measurement circuit.

12. The measurement instrument according to claim 1, wherein a modulation scheme of the RF signal is unknown to the measurement circuit.

13. The measurement instrument according to claim 1, wherein the analysis circuit is configured to determine erroneous error vectors.

14. The measurement instrument according to claim 13, wherein the analysis circuit is configured to determine erroneous components of the erroneous error vectors.

15. The measurement instrument of claim 13, wherein the analysis circuit is configured to correct the determined erroneous error vectors.

16. The measurement instrument of claim 13, wherein the analysis circuit is configured to discard the determined erroneous error vectors.

17. The measurement instrument according to claim 1, wherein the measurement instrument is a signal analyzer, a spectrum analyzer, or an oscilloscope.
